(19) United States
(12) Patent Application Publication
(10) Pub. No.: US 2001/0005051 A1
(43) Pub. Date: Jun. 28, 2001

(54) Semiconductor package and semiconductor device

(76) Inventors: Yukiharu Takeuchi, Nagano-shi (JP); Yukari Hatcho, Nagano-shi (JP)

Correspondence Address: Paul & Paul, 2900 Two Thousand Market Street, Philadelphia, PA, 19103, US

(21) Appl. No.: 09/734,864

(22) Filed: Dec. 12, 2000

(30) Foreign Application Priority Data
Dec. 14, 1999 (JP) 11-354193

(51) Int. Cl. H01L 23/34

(52) U.S. Cl. 257/712

(57) ABSTRACT

A semiconductor package capable of quickly and satisfactorily dissipating to the outside the heat generated from a semiconductor chip mounted in it and in turn capable of contributing to an improvement of the operational reliability of the semiconductor chip, provided with an interconnection substrate, a heat dissipation plate bonded to one surface of the interconnection substrate, a cavity formed in another surface of the interconnection substrate for with mounting a semiconductor chip, a plurality of external connection terminals arranged in a grid on the other surface of the interconnection substrate around the cavity, and through holes formed with conductor layers on their inside walls formed at a periphery of the interconnection substrate and penetrating through the interconnection substrate so as to reach the heat dissipation plate, and a semiconductor device using the same.

### BACKGROUND OF THE INVENTION

1. Field of the Invention

The present invention relates to a package provided for mounting a semiconductor chip (hereinafter referred to as a “semiconductor package”) and to a semiconductor device, more particularly relates to a technique useful for improving heat dissipation in a ball grid array (BGA) or pin grid array (PGA) or other surface-mounting type semiconductor package.

2. Description of the Related Art

FIG. 1 schematically shows the configuration of a semiconductor package of an example of the related art in (a) cross-sectional and (b) plan views.

The illustrated example shows a package proposed in JP-A-9-107053 by the present assignee and specifically shows a BGA type package of a cavity down structure. FIG. 1(a) shows the sectional structure of the semiconductor package, while FIG. 1(b) shows part of an array of external connection terminals as seen from the bottom side of the semiconductor package (quarter portion in the illustrated example).

In FIG. 1(a), 1 denotes a semiconductor package, 2 a semiconductor chip to be mounted on the semiconductor package 1, and 3 a mother board such as a printed circuit board for mounting the semiconductor package 1 with the semiconductor chip 2 mounted thereon. The illustrated example shows the state of the semiconductor package 1 with the semiconductor chip 2 mounted on it, that is, the semiconductor device, mounted on the mother board 3.

The semiconductor package 1 is basically constituted by an interconnection substrate 10 and a heat spreader or other heat dissipation plate 11. The heat dissipation plate 11 is bonded to one surface (top surface in the illustrated example) of the interconnection substrate 10 by a bonding sheet 12.

Further, a cavity 10H having a larger area than a region for mounting the semiconductor chip 2 therein is formed at the center of the interconnection substrate 10. A plurality of solder bumps 13 used as external connection terminals for mounting the semiconductor package on the mother board 3 are arranged in the form of a grid on the other surface (bottom surface in the illustrated example) of the interconnection substrate 10 around this cavity (refer to FIG. 1(b)). Further, the interconnection substrate 10 has a resin layer (insulation layer) 14 for constituting the core of the substrate, interconnection layers (conductor layers) 15 including pads or the like formed by patterning on both surfaces of this resin layer 14, and solder resist layers 16 serving as protective films formed so as to cover the resin layer 14 and the interconnection layers 15 except at the pad portions and bonding portions of these interconnection layers 15. The pad portions of the interconnection layers 15 exposed from these solder resist layers 16 are used as terminal forming portions. The solder bumps 13 are joined to these terminal forming portions (pads).

The semiconductor chip 2 is arranged in the cavity provided at the center of the interconnection substrate 10. The top surface of the semiconductor chip 2 at the opposite side from the bottom surface provided with electrodes (not illustrated) is bonded to the heat dissipation plate 11 by a bonding material 21. At the same time, the electrodes are connected to the bonding portions of the interconnection layers 15 exposed from the solder resist layers 16 of the interconnection substrate 10 by bonding wires 22. Further, by filling the cavity with a sealing resin 23, the bonding wires 22 are held and the bonding strength of the semiconductor chip 2 with respect to the package 1 is raised.

As explained above, according to the configuration of the semiconductor package 1 shown in FIG. 1, when the semiconductor chip 2 is mounted and operated, heat generated from the semiconductor chip 2 is dissipated to the outside of the package via the heat dissipation plate 11 thermally directly connected to the semiconductor chip 2. In this case, part of the generated heat is conducted through the sealing resin 23 as seen also from the structure shown in FIG. 1 and dissipated to the outside of the package through the medium of the air in the space with the mother board 3.

However, the heat is dissipated from a lower portion of the package through the medium of the sealing resin 23, which does not have that high a heat conductivity, and the air. Therefore, when compared with the heat dissipation from the upper portion of the package through the medium of the heat dissipation plate 11, the amount of heat dissipated is small and not always sufficient from the viewpoint of the heat dissipation effect.

As a technique for coping with this, for example Japanese Unexamined Patent Publication (Kokai) No. 7-302866 discloses a BGA type package of a cavity down structure provided with through holes (thermal via holes) for heat dissipation penetrating through the multilayer interconnection substrate in a vertical direction. According to this structure, the heat generated from the semiconductor chip is dissipated from the upper portion of the interconnection substrate via the heat spreader (heat dissipation plate) and, at the same time, dissipated from the lower portion of the interconnection substrate through the thermal via holes.

However, this related art (Japanese Unexamined Patent Publication No. 7-302,866) only disclosed providing thermal via holes in the interconnection substrate in order to raise the heat dissipation property in a package of a cavity down structure and did not specifically describe in which portion of the interconnection substrate to provide the thermal via holes. At least, when referring to FIG. 2 of this publication, the thermal via holes are formed in the vicinity of the semiconductor chip, that is, the portion near the center of the interconnection substrate.

Therefore, according to the disclosure of this related art, in the process of the heat conducted through the thermal via holes formed in the portion near the center of the interconnection substrate being conducted between the interconnection substrate of the package and the printed circuit board for mounting the package toward the outside of the package, the external connection terminals (bumps) of the interconnection substrate in the middle thereof constitute significant obstacles. Therefore, there may be the problem of the heat not necessarily being smoothly dissipated to the outside of the package. In some cases, there may be the problem of the heat remaining between the interconnection substrate and the printed circuit board and the heat therefore not being quickly or satisfactorily dissipated to the outside of the package.

There is a high possibility of this problem occurring more seriously in situations where external connection terminals (bumps or pins) are arranged with a higher density along with the demands on recent semiconductor packages for reduction of size or for increased number of pins.

Further, if the heat remains between the interconnection substrate of the package and the substrate for mounting the package, the temperature of the semiconductor chip mounted on the package will remain high as it is and may have an adverse influence upon the operational reliability of the chip.

### SUMMARY OF THE INVENTION

An object of the present invention is to provide a semiconductor package capable of quickly and satisfactorily dissipating to the outside the heat generated from a semiconductor chip mounted in it and in turn capable of contributing to an improvement of the operational reliability of the semiconductor chip and a semiconductor device using the same.

To achieve this object, according to a first aspect of the present invention, there is provided a semiconductor package comprising an interconnection substrate, a heat dissipation plate bonded to one surface of the interconnection substrate, a cavity formed in another surface of the interconnection substrate for mounting a semiconductor chip, a plurality of external connection terminals arranged in a grid on the other surface of the interconnection substrate around the cavity, and through holes formed with conductor layers on their inside walls formed at a periphery of the interconnection substrate and penetrating through the interconnection substrate so as to reach the heat dissipation plate.

Further, according to a second aspect of the present invention, there is provided a semiconductor device comprised of the semiconductor package and a semiconductor chip mounted in the cavity with electrodes of the semiconductor chip electrically connected to the external connection terminals via interconnections provided at the interconnection substrate.

According to these configurations of the semiconductor package and the semiconductor device according to the present invention, since through holes for heat dissipation (thermal via holes) are formed in the vicinity of the periphery of the interconnection substrate and penetrate through the interconnection substrate to reach the heat dissipation plate, in addition to the dissipation of the heat generated from the semiconductor chip mounted in the cavity of the package to the outside of the package (one surface of the interconnection substrate) by a heat dissipation plate similar to the related art, the heat can be further effectively dissipated from this heat dissipation plate to the outside of the package (other surface of the interconnection substrate) through the thermal via holes.

Namely, by providing the thermal via holes at specific positions (vicinity of the periphery) of the interconnection substrate, the problem envisioned in the related art (Japanese Unexamined Patent Publication No. 7-302866) is solved and it becomes possible to quickly and satisfactorily dissipate the heat which is conducted through the thermal via holes to the outside of the package. This contributes to the improvement of the operational reliability of the semiconductor chip.

### BRIEF DESCRIPTION OF THE DRAWINGS

These and other objects and features of the present invention will become clearer from the following description of the preferred embodiments of the invention given with reference to the attached drawings, in which:

FIG. 1 schematically shows the configuration of a semiconductor package of an example of the related art in (a) cross-sectional and (b) plan views;

FIG. 2 schematically shows the configuration of a semiconductor package according to a first embodiment of the present invention in (a) cross-sectional and (b) plan views;

FIG. 3 schematically shows the configuration of a semiconductor package according to a second embodiment of the present invention in (a) cross-sectional and (b) plan views; and

FIG. 4 is a graph of the effects achieved by the embodiments in comparison with the related art.

### DESCRIPTION OF THE PREFERRED EMBODIMENTS

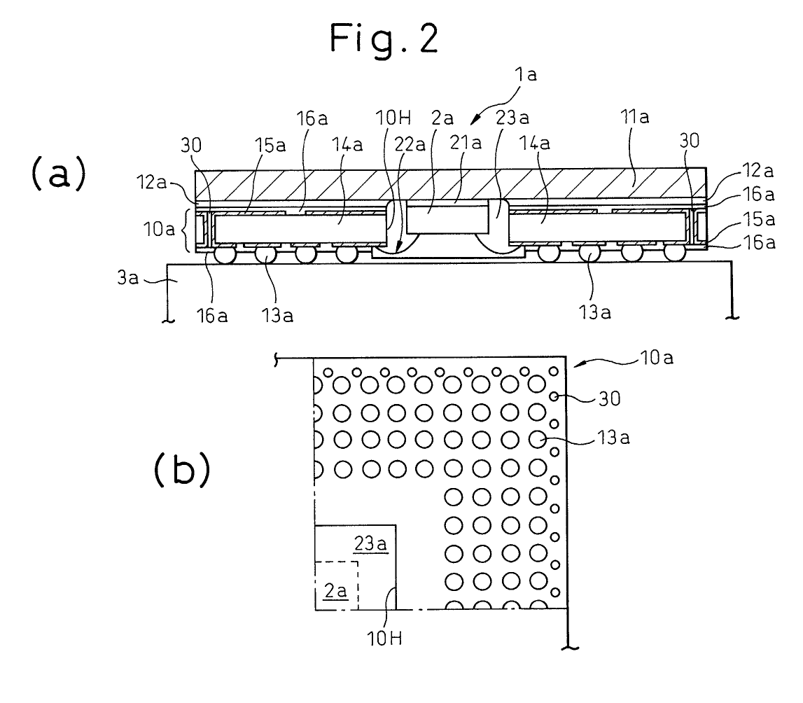

FIG. 2 schematically shows the configuration of a semiconductor package according to a first embodiment of the present invention and specifically shows a BGA type package of a cavity down structure.

FIG. 2(a) shows the sectional structure of the semiconductor package, while FIG. 2(b) shows part of an array of external connection terminals and thermal via holes characterizing the present invention (quarter portion in the illustrated example) seen from the bottom surface of the semiconductor package.

Reference numeral 1a denotes a semiconductor package, 2 a semiconductor chip mounted in the semiconductor package 1a, and 3a a mother board such as a printed circuit board for mounting the semiconductor package 1a mounted with the semiconductor chip 2a thereon. The illustrated example shows that state of the semiconductor package 1a mounted with the semiconductor chip 2a, that is, the semiconductor device, mounted on the mother board 3a.

The semiconductor package 1a is basically constituted by an interconnection substrate 10a having terminal forming portions (pads) to which are bonded external connection terminals (bumps) used for mounting the semiconductor package on the mother board 3a and a heat spreader or other heat dissipation plate 11a for dissipating to the outside the heat generated from the mounted semiconductor chip 2a. The heat dissipation plate 11a is bonded to one surface (top surface in the illustrated example) of the interconnection substrate 10 by a bonding sheet 12a. A prepreg is used as the bonding sheet 12a. For example, use is made of a reinforcing glass fabric impregnated with a BT resin or other thermosetting resin and formed into a semicured B stage.

Further, at the center of the interconnection substrate 10a is formed a cavity 10H having a larger area than the region for mounting the semiconductor chip 2a. A plurality of solder bumps 13a serving as the external connection terminals are arranged in a grid at the other surface (bottom surface in the illustrated example) of the interconnection substrate 10a around this cavity (refer to FIG. 2(b)).

Further, in the interconnection substrate 10a, 14a denotes a resin layer (insulation layer) constituting the core of the substrate, 30 through holes formed at specific positions of the resin layer 14a, 15a interconnection layers (conductor layers) including the inside walls of the through hole 30 and including the pads etc. formed by patterning on the two surfaces of the resin layer 14a, and 16a solder resist layers serving as protective films formed so as to cover the resin layer 14a and the interconnection layers 15a except at the pad portions and the bonding portions of the interconnection layers 15. The pad portions of the interconnection layers 15a exposed from the solder resist layers 16a are used as the terminal forming portions. By bonding solder balls to these terminal forming portions (pads) by reflow, solder bumps 13a serving as the external connection terminals are formed. As the material of the resin layer 14a, use is made of for example a BT resin. Further, for the interconnection layers 15a, typically copper (Cu) is used. The layers are formed by for example electroless plating or electrolytic plating.

On the other hand, the semiconductor chip 2a is arranged in the cavity 10H provided at the center of the interconnection substrate 10a, the top surface of the semiconductor chip 2a on the opposite side from the bottom face side where the electrodes are provided (not illustrated) is bonded to the heat dissipation plate 11a by a bonding material 21a such as a silver (Ag) paste having a relatively high heat conductivity. At the same time, the electrodes are connected to the bonding portions of the interconnection layers 15a exposed from the solder resist layers 16a of the interconnection substrate 10a by bonding wires 22a. Further, the cavity is filled with a sealing resin 23a such as an epoxy resin to hold the bonding wires 22a and, at the same time, raise the bonding strength of the semiconductor chip 2a with respect to the package 1a.

Further, when mounting the semiconductor package 1a on the mother board 3a, the solder bumps 13a are bonded to the corresponding electrode pads on the mother board 3a by reflow to connect the two.

The through holes 30 formed so as to penetrate through the interconnection substrate 10a in the vertical direction and reach the heat dissipation plate 11a constitute the thermal via holes characterizing the present invention. These thermal via holes 30 are provided at specific positions of the interconnection substrate 10a, that is, in the vicinity of the periphery of the interconnection substrate 10a. In the present embodiment, one row of thermal via holes 30 is formed along the outside of the outermost row of solder bumps 13a among the plurality of solder bumps arranged in a grid on the interconnection substrate 10a (refer to FIG. 2B). Note that, a resin (insulator) such as an epoxy resin is filled in the thermal via holes 30.

According to the configuration of the semiconductor package 1a of the present embodiment, the heat generated from the semiconductor chip 2a mounted in the cavity provided at the center of the interconnection substrate 10a is dissipated upward from the package via the heat dissipation plate 11a and effectively dissipated downward from the package from this heat dissipation plate 11a through the thermal via holes 30.

At this time, concerning the latter heat dissipation, since the thermal via holes 30 are provided outside of the outermost row of solder bumps 13a on the interconnection substrate 10a, the problem envisioned in the related art (Japanese Unexamined Patent Publication No. 7-302866), that is, the problem of the heat conducted through the thermal via holes being blocked by the bumps of the interconnection substrate and not smoothly dissipating to the outside of the package, is not caused. The heat conducted through the thermal via holes 30 can be quickly and satisfactorily dissipated to the outside of the package.

By this, the operating temperature of the semiconductor chip 2a can be maintained within a prescribed range, and it becomes possible to improve the operational reliability.

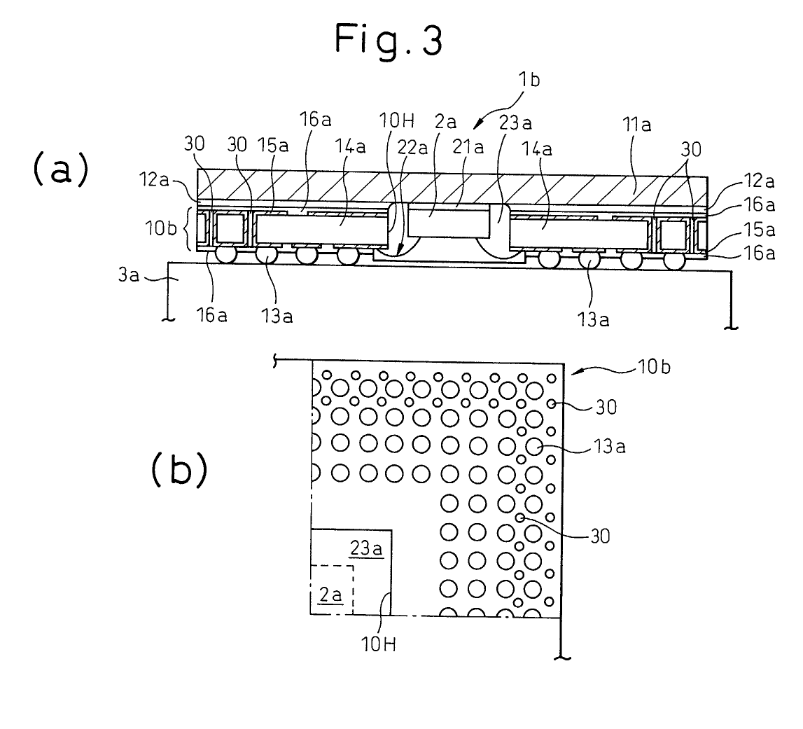

FIG. 3 schematically shows the configuration of a semiconductor package according to a second embodiment of the present invention and show a BGA type package of the cavity down structure similar to the first embodiment (refer to FIG. 2). Further, FIG. 3 shows a sectional structure and array corresponding to those shown in FIG. 2.

The semiconductor package 1b of this second embodiment is different from the semiconductor package 1a of the first embodiment in the point that each one row of the thermal via holes 30 each is formed at the outside and the immediate inside of the outermost row of the solder bumps 13a on the interconnection substrate 10, that is, two rows in total. The rest of the configuration is the same as that of the case of the first embodiment, so an explanation thereof is omitted.

According to the configuration of the semiconductor package 1b of the present embodiment, in comparison with the case of the first embodiment, the heat can be further effectively dissipated to the outside of the package by the amount of the increase of the number of the thermal via holes 30 provided at specific positions (in the vicinity of the periphery) of the interconnection substrate 10a.

In the above embodiments, the explanation was made of the case where the interconnection substrates 10a and 10b had two interconnection layers (interconnection layers 15a formed on the two surfaces of the resin layer 14a), but the number of the interconnection layers is not limited to two and of course can be set to three or more. In this case as well, the interconnection layers are connected to each other via the conductor layers formed on the inside walls of the thermal via holes 30.

Further, in the packages 1a and 1b of the above embodiments, the explanation was made of the case where solder bumps 13a were used as the external connection terminals for mounting the semiconductor package on the mother board 3a, but of course the material and the form of the external connection terminal are not limited to this. For example, use can be made of gold (Au) bumps too in place of the solder bumps 13a, and it is also possible to form the terminals as pins.

When using pins as the external connection terminals of the semiconductor package 1a (1b), the pins are bonded as follows. First, appropriate amounts of solder paste are placed on the pad portions (terminal forming portions) of the conductor layers 15a exposed from the solder resist layers 16a at the bottom surface of the interconnection substrate 10a (10b). The head portions of the T-shaped pins having heads of for example the diameter size are arranged on these. The solder pastes are then made to reflow and solidify to bond the pins. When mounting the semiconductor package 1a (1b) on the mother board 3a, similarly suitable amounts of solder paste are placed on the corresponding electrode pads of the mother board 3a, the leg portions of the T-shaped pins are placed against them, and the solder pastes are made to reflow and solidify.

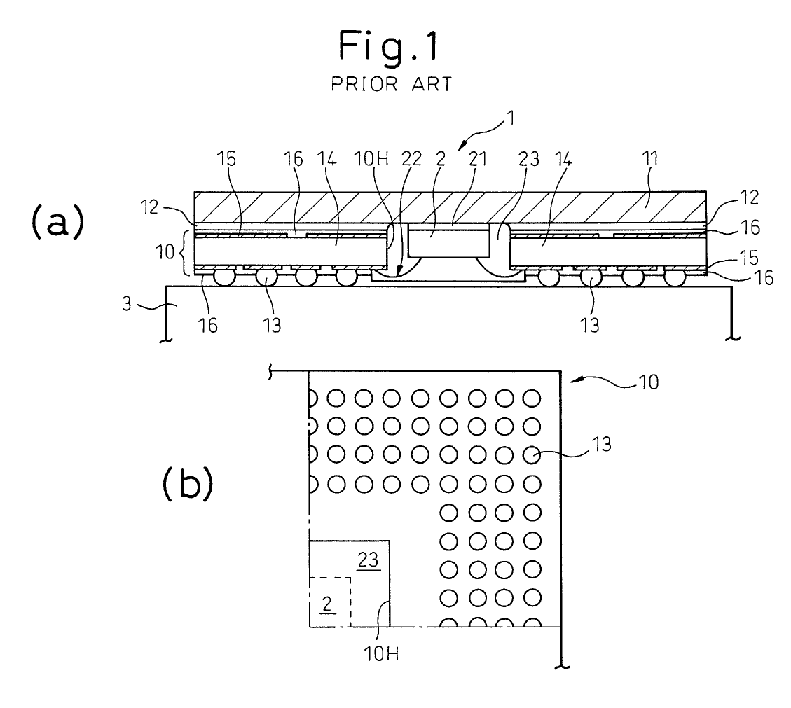

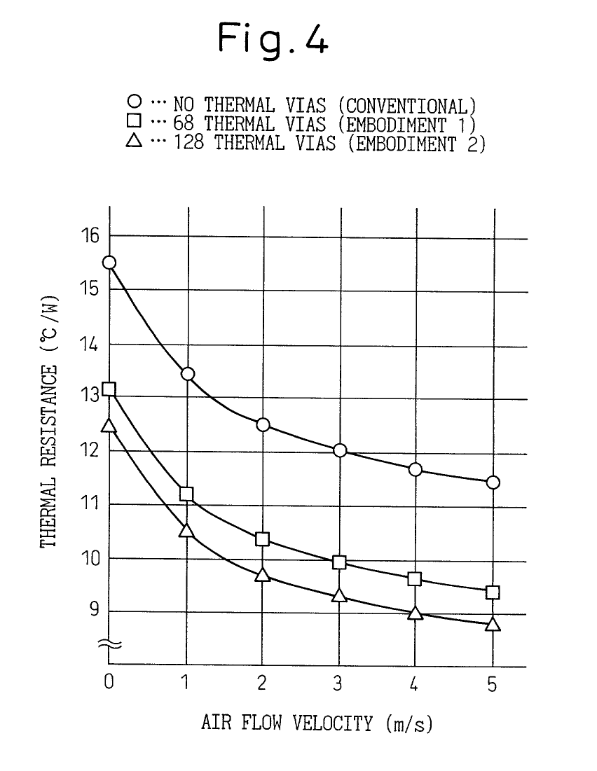

FIG. 4 shows the effects obtained from the first and second embodiments (refer to FIGS. 2A and 2B and FIGS. 3A and 3B) in comparison with the case of the related art (refer to FIG. 1) and shows results of simulation for the embodiments and the related art using a specific example as a model.

The structure and conditions of the model were as follows.

Ambient temperature: 40° C.

Chip power consumption: 10 W

Size of semiconductor chip: 5.2×5.2×0.4 mm

Size of semiconductor package: 23×23 mm

Size of cavity: 7×7 mm

Mother board: FR-4 (heat resistant glass fabric-based, epoxy resin-impregnated, copper-clad board)

Size of mother board: 130×180×1.6 mm

Bump: Eutectic solder of lead (Pb)/tin (Sn)

Pitch of bumps: 1.27 mm

Number of bumps: 208 (=17×17−9×9)

Outer diameter/inner diameter of thermal via holes: 0.3 mm/0.26 mm

Number of thermal via holes (first/second embodiment): 68/128

Heat dissipation plate: Cu plate having thickness of 0.5 mm

Bonding material: Ag paste having thickness of 0.05 mm

Bonding sheet: BT prepreg having thickness of 0.06 mm

Insulation layer: BT resin layer having thickness of 0.5 mm

Conductor layer (Cu layer)/solder resist layer: Thickness of 0.018 mm

Distance between sealing resin (epoxy resin) and mother board: 0.13 mm

Based on the above structure and conditions, the change of heat resistance [°C/W] of each package when changing the velocity of the air flow from a blower (not illustrated) from 0 to 1, 2, 3, 4, and 5 m/s represented by the simulation is shown in FIG. 4.

As shown in FIG. 4, it is seen that the heat resistance [°C/W] can be reduced in the first and second embodiments providing the thermal via holes at specific positions in comparison with the related art not providing the thermal via holes. Further, it is seen that the heat resistance [°C/W] can be made smaller in the second embodiment having a larger number of thermal via holes than that of the first embodiment in comparison with the first embodiment. For example, the heat resistance [°C/W] when the air flow rate is 1 m/s is smaller in the first embodiment by about 2.2 °C/W in comparison with the relate art, while is smaller in the second embodiment by about 0.7 °C/W in comparison with the first embodiment. Similar results appear also for the cases of the other air flow rates.

This means that the first and second embodiments are better in the heat dissipation effect than the related art and that the second embodiment is better in the heat dissipation effect than the first embodiment.

As explained above, according to the present invention, by providing the thermal via holes in the vicinity of the periphery of the interconnection substrate, the heat generated from the mounted semiconductor chip can be quickly and satisfactorily dissipated to the outside of the package and thereby it becomes possible to improve the operational reliability of the semiconductor chip.

While the invention has been described with reference to specific embodiment chosen for purpose of illustration, it should be apparent that numerous modifications could be made thereto by those skilled in the art without departing from the basic concept and scope of the invention.

1. A semiconductor package comprising:
an interconnection substrate,
a heat dissipation plate bonded to one surface of the interconnection substrate,
a cavity formed in another surface of said interconnection substrate for mounting a semiconductor chip,
a plurality of external connection terminals arranged in a grid on the other surface of the interconnection substrate around the cavity, and
through holes formed with conductor layers on their inside walls formed at a periphery of said interconnection substrate and penetrating through the interconnection substrate so as to reach said heat dissipation plate.

2. A semiconductor package as set forth in claim 1, wherein said through holes are formed in a single row outside an outermost row of external connection terminals arrayed on the interconnection substrate.

3. A semiconductor package as set forth in claim 1, wherein said through holes are formed in two rows at the outside and immediate inside of an outermost row of external connection terminals arrayed on the interconnection substrate.

4. A semiconductor package as set forth in claim 1, wherein said interconnection substrate has at least two interconnection layers and said interconnection layers are electrically connected through the conductor layers formed at the inside walls of the through holes.

5. A semiconductor package as set forth in claim 1, wherein an insulator is filled inside the through holes.

6. A semiconductor package as set forth in claim 1, wherein said external connection terminals are one of solder bumps and gold bumps.

7. A semiconductor package as set forth in claim 1, wherein said external connection terminals are pins.

8. A semiconductor device comprising:
a semiconductor package as set forth in any one of claims 1 to 7 and
a semiconductor chip mounted in said cavity with electrodes of the semiconductor chip electrically connected to said external connection terminals via interconnections provided at said interconnection substrate.
